(19) United States
(12) Patent Application Publication
(10) Pub. No.: US 2025/0207242 A1
(43) Pub. Date: Jun. 26, 2025

(54) METHOD FOR PRODUCING AND TRANSFERRING A TWO-DIMENSIONAL MATERIAL

(71) Applicant: COMMISSARIAT A L'ENERGIE ATOMIQUE ET AUX ENERGIES ALTERNATIVES, PARIS (FR)

(72) Inventors: Franck FOURNEL, GRENOBLE CEDEX 09 (FR); Emmanuel ROLLAND, GRENOBLE CEDEX 09 (FR); Lucie LE VAN-JODIN, GRENOBLE CEDEX 09 (FR); Paul BRUNET, GRENOBLE CEDEX 09 (FR)

(21) Appl. No.: 18/990,780

(22) Filed: Dec. 20, 2024

(30) Foreign Application Priority Data
Dec. 21, 2023 (FR) 2314917

(51) Int. Cl. C23C 16/01; H01L 21/02

(52) U.S. Cl. CPC C23C 16/01; H01L 21/02568

(57) ABSTRACT

A method for producing and transferring a two-dimensional material, includes growing a two-dimensional material on a surface of a growth substrate such that the two-dimensional material is linked to the surface of the growth substrate by van der Waals forces, the surface of the growth substrate having a first contact angle with a drop of a liquid; providing a target substrate, the target substrate having a surface with a second contact angle with a drop of the liquid, the second contact angle being strictly greater than the first contact angle; assembling the growth substrate and the target substrate by direct bonding between the two-dimensional material and the surface of the target substrate; and breaking the interface between the growth substrate and the two-dimensional material by propagating an interfacial crack at the interface between the two-dimensional material and the growth substrate, the crack front being wetted with the liquid.

### CROSS-REFERENCE TO RELATED APPLICATIONS

This application claims priority to French Patent Application No. 2314917, filed Dec. 21, 2023, the entire content of which is incorporated herein by reference in its entirety.

### FIELD

The present invention is concerned with two-dimensional materials. The invention more particularly relates to a method for producing and transferring a two-dimensional material.

### BACKGROUND

Two-dimensional (2D) materials, such as graphene and transition metal dichalcogenides (MoS₂, MoSe₂, MoTe₂, WS₂, WSe₂ . . . ), are in the form of an atomic or molecular monolayer or a stack of monolayers linked together by van der Waals forces. These materials have excellent mechanical, electrical, optical and thermal properties, making them the materials of choice for many applications in fields as varied as information technology, communication technology, health, energy and transport.

2D materials are also considered promising in the field of micro/nanoelectronics, as they allow crystalline layers with a very low thickness, typically less than one nanometre, to be obtained. Making electronic components (such as transistors or photodetectors) of nanometric dimensions on substrates of various kinds is thus contemplated, using the two-dimensional material as a semiconductor material.

Growing a 2D material is generally carried out at a very high temperature (800° C.-1200° C.), which is often incompatible with the substrate, referred to as the target substrate or final substrate, onto which this two-dimensional material is desired to be integrated. Indeed, this target substrate can already support components (or parts of components) that would be degraded during the synthesis of the 2D material. To overcome this problem, the growth and integration steps are dissociated. The 2D material is grown on an adapted growth substrate and then transferred from its growth substrate to the substrate of interest. The main difficulty lies in preserving intrinsic properties of the 2D material after transfer.

Document [“Transfer of Large-scale two dimensional semiconductors: challenges and developments”, Watson et al, 2D materials, 8, 2021, 032001] describes several known transfer methods.

A first category of methods uses a support layer (of polymer or metal) disposed on the 2D material. This support layer provides mechanical support for the 2D material during transfer, mainly between the moment when the 2D material is detached from the growth substrate and the moment when it is placed on the target substrate. This reduces deformation of the 2D material during transfer.

Documents [“Surface-energy-assisted perfect transfer of centimeter-scale monolayer and few-layer MoS₂ films onto arbitrary substrates”, Gurarslan et al., ACS Nano, 2014 Nov. 25; 8(11):11522-8] and [“Large-Area Transfer of 2D TMDCs Assisted by a Water-Soluble Layer for Potential Device Applications”, Madan Sharma et al, ACS Omega 2022, 7, 11731-11741] describe two examples of transfer methods using a polymer layer.

Documents [“Layer-engineered atomic-scale spalling of 2D van der Waals crystals”, Ji-Yun Moon et al., Matter, 5, 3935-3946, 2022] and [“Controlled crack propagation for atomic precision handling of wafer-scale two-dimensional materials”, Jaewoo Shim et al., Science 362, 665-670, 2018] describe two examples of a transfer method using a metal support layer.

Using a metal rather than a polymer support layer avoids leaving polymer residues on the 2D material. However, metal residues and cracks can be generated on the 2D material.

A second category of transfer methods does not use a support layer. This avoids any polymer or metal residue on the 2D material.

Document [“Centimeter-scale Green Integration of Layer-by-Layer 2D TMD vdW Heterostructures on Arbitrary Substrates by Water-Assisted Layer Transfer”, Kim et al, Scientific reports, 9, 1641, 2019] describes a method that dispenses with the support layer.

The 2D material disposed on the growth substrate is soaked in water. Water causes immediate delamination of the 2D material, which detaches from the growth substrate and floats on the surface of water. The 2D material, now in the form of a thin film, has then to be recovered and placed on the target substrate.

Allowing a film as thin as 2D material to float and then manipulating it without mechanical support brings wrinkles and holes thereon. These defects persist once the 2D material has been bonded to the target substrate and contribute to deteriorating performance of the final device. They are especially detrimental when optical and photoluminescence applications are contemplated.

Moreover, handling 2D material in water (or, more generally, in any type of liquid) is not adapted either to the transfer of layers with a surface area of more than a few square centimetres, or to the clean-room environment of the microelectronics industry.

### SUMMARY

There is therefore a need to improve existing methods for transferring 2D material onto a given target substrate.

In particular, there is a need for a method for producing and transferring a 2D material which generates neither polymer and/or metal residues nor mechanical deformations in the 2D material.

According to an aspect of the invention, this need tends to be satisfied by providing a method for producing and transferring a two-dimensional material, comprising the following steps of:
Growing the two-dimensional material on a surface of a growth substrate such that the two-dimensional material is linked to the surface of the growth substrate by van der Waals forces, the surface of the growth substrate having a first contact angle with a drop of a liquid;
Providing a target substrate, the target substrate having a surface with a second contact angle with a drop of the liquid, the second contact angle being strictly greater than the first contact angle;
Assembling the growth substrate and the target substrate by direct bonding between the two-dimensional material and the surface of the target substrate; and
Breaking the interface between the growth substrate and the two-dimensional material, by applying a mechanical load to the assembly of the growth substrate and the target substrate to generate and propagate a crack front at the interface between the growth substrate and the two-dimensional material, and by placing the assembly of the growth substrate and the target substrate in an environment such that a liquid front forms at the interface between the growth substrate and the two-dimensional material, the mechanical load being configured so that the crack front is wetted with the liquid.

Thus the surface of the growth substrate and the mechanical load are configured so that the crack front is wetted with the liquid throughout the propagation of the crack. This allows the two-dimensional material and growth substrate to be separated by adhesive failure, as the crack is confined to the interface between the growth substrate and the two-dimensional material.

In addition, providing a lower wettability (to the liquid) of the surface of the target substrate than the growth substrate surface makes it possible to obtain a weakened interface between the growth substrate and the two-dimensional material. Adhesive failure will occur at this interface and not at the interface between the target substrate and the two-dimensional material, which is therefore more resistant to such adhesive failure.

This allows the stresses to be relaxed upon implementing the mechanical load, and therefore the growth substrate can be separated from the target substrate (with the two-dimensional material bonded to the target substrate) readily, without the need for complex equipment, for example by making a simple separation by wedge insertion.

The different contact angle, and therefore wettability, of the surfaces of the target substrate and the growth substrate further enables a method to be adapted to a wide variety of combinations of substrates and two-dimensional materials relative to methods based on intrinsic properties of the substrates and/or the two-dimensional material. Indeed, the wettable nature of substrates is not necessarily an intrinsic property of the substrate. It can be easily acquired (substrates with low wettability can be made very wettable or vice versa) using, for example, physico-chemical surface treatments.

In addition, by virtue of direct bonding, the target substrate acts as a support layer for the two-dimensional material. This allows the two-dimensional material to be held mechanically during transfer, while eliminating steps of forming and removing a support layer (because they are no longer necessary).

The absence of the support layer further avoids any polymer or metal residue (as these are linked to the support layer), nor does it cause any damage as no material is deposited onto the 2D material.

Direct bonding, like the breaking step, is furthermore compatible with the microelectronics industry and applicable to large-area 2D material layers. Direct bonding is indeed commonly used on a large scale and on 300 mm wafers to transfer thin semiconductor layers.

Further to the characteristics just discussed in the preceding paragraphs, the production and transfer method according to an aspect of the invention may have one or more additional characteristics from among the following, considered individually or according to any technically possible combination:
The difference between the first and second contact angles is strictly greater than 10°, for example greater than 30°, such as greater than 50°.
Providing the target substrate comprises treating the surface of the target substrate to increase the second contact angle.
The method comprises, prior to the step of growing the two-dimensional material, a step of treating the surface of the growth substrate so as to reduce the first contact angle.
The mechanical load is configured to allow the crack front to advance at a speed of less than or equal to 100 μm/s, for example less than or equal to 10 μm/s, and such as less than or equal to 1 μm/s.
The mechanical load is exerted by a blade with a thickness of less than or equal to 500 μm, for example than or equal to 300 μm, and such as less than or equal to 100 μm.
The thickness of the blade is less than or equal to 100 μm, and the blade is inserted at a first speed to initiate the crack and at a second speed to propagate the crack into the interface between the growth substrate and the two-dimensional material, the first speed being less than or equal to 1 μm/s, and the second speed being greater than the first speed and less than or equal to 100 μm/s.
In the step of breaking the interface between the growth substrate and the two-dimensional material, the assembly of growth substrate and target substrate is placed in the liquid.
The liquid is deionised water or an ionic solution.
During the step of breaking the interface between the growth substrate and the two-dimensional material, the assembly of growth substrate and target substrate is placed in a gaseous medium comprising deionised water vapour or ionic solution vapour.
The two-dimensional material is in an embodiment graphene, hexagonal crystal structure boron nitride (h-BN) or a transition metal dichalcogenide.
The surface of the growth substrate and the surface of the target substrate are each formed of a material selected from silicon (Si), germanium (Ge), silicon dioxide (SiO₂), silicon carbide (SiC), indium phosphide (InP), gallium arsenide (AsGa) and sapphire (Al₂O₃).
The surface of the growth substrate is formed of a silicon or germanium base layer covered or not with a surface layer of a material selected from the following materials: aluminium (Al), silicon nitride (Si₃N₄), copper (Cu), titanium (Ti), alumina (Al₂O₃), silicon dioxide (SiO₂), hafnium oxide (HfO₂), nickel (Ni), graphene.

### BRIEF DESCRIPTION OF THE FIGURES

Further characteristics and benefits of the invention will become clearer from the description given below, by way of indicating and in no way limiting purposes, with reference to the appended figures, in which:

FIGS. 1A to 1C schematically represent steps of a method for producing and transferring 2D material according to an embodiment of the invention;

FIG. 2 schematically represents, on the one hand, a drop of liquid deposited onto the surface of a growth substrate in accordance with an embodiment of the invention and, on the other hand, a drop deposited onto the surface of a target substrate in accordance with an embodiment of the invention;

FIG. 3 represents, for different target substrates, measurements of the drop contact angle of each surface of the target substrate as a function of a concentration of CF₄ and SF₆, obtained after treatment of these surfaces;

FIG. 4 is a top view photograph of the growth substrate obtained at the end of a first exemplary embodiment of the method represented in FIGS. 1A to 1C, the non-transferred two-dimensional material appears in dark grey;

FIG. 5 is a top view photograph of the growth substrate obtained at the end of a second exemplary embodiment of the method represented in FIGS. 1A to 1C, the non-transferred two-dimensional material appears in dark grey.

For greater clarity, identical or similar elements are identified by identical reference signs throughout the figures.

### DETAILED DESCRIPTION

The present invention aims at improving methods for transferring a two-dimensional material onto a substrate of interest, also referred to as a target substrate.

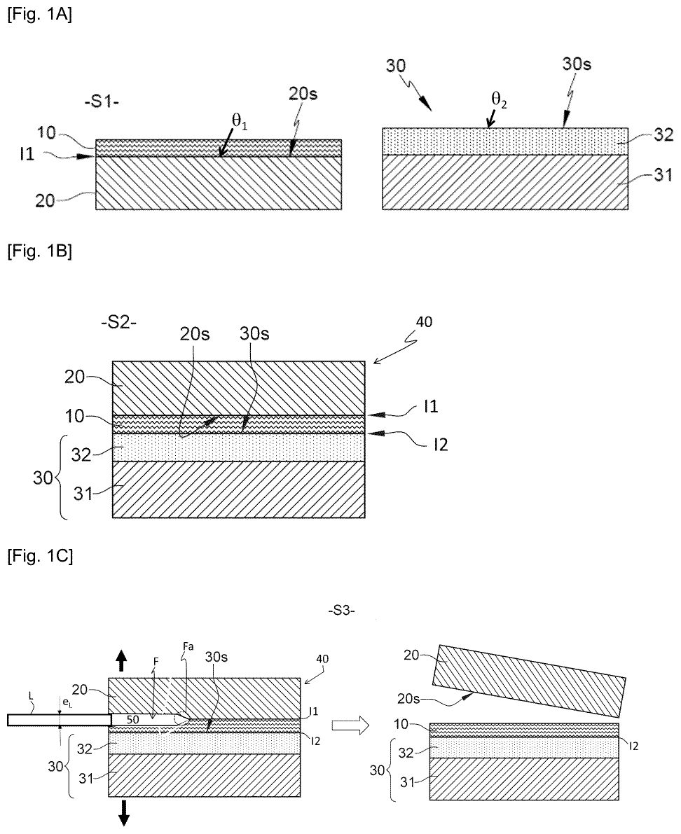

FIGS. 1A to 1C illustrate steps S1 to S3 of a method for producing and transferring a two-dimensional material 10. According to this method, the two-dimensional material 10 is transferred from a growth substrate 20 to a support substrate 30, hereinafter noted as “target substrate 30”.

A two-dimensional (2D) material designates a material comprised of a mono-atomic or mono-molecular sheet (also referred to as a monolayer) or a stack of N identical mono-atomic or mono-molecular sheets (N being a natural number greater than or equal to 2). By identical layers, it is meant layers having atoms or molecules of the same nature and ordered in the same way. The 2D material is said to be “monolayer” when it comprises a single sheet and “multilayer” when it comprises several sheets. Within each sheet, the atoms (or molecules) are linked together by covalent bonds. The different sheets of a 2D multilayer material are linked together by van der Waals forces.

The material is considered herein to have “2D” properties when it comprises less than ten mono-atomic or mono-molecular layers (N<10, for example N=3). Beyond that, its properties are those of a bulk material.

Step S1 represented by FIG. 1A comprises providing the growth substrate 20, growing the 2D material 10 from a surface 20s of the growth substrate 20, as well as providing the target substrate 30.

At the atomic scale, the 2D material 10 is thus linked (or adhered) to the surface 20s of the growth substrate 20 by van der Waals forces. The interface between the 2D material and the growth substrate 20 is noted “I1” in the figures.

The 2D material 10 can be graphene, hexagonal crystal structure boron nitride (h-BN) or a transition metal dichalcogenide, such as tungsten disulphide (WS₂), molybdenum disulphide (MoS₂), molybdenum diselenide (MoSe₂) or tungsten diselenide (WSe₂).

The growth substrate 20 is a wafer.

The growth substrate 20 has a free surface 20s (hereinafter simply noted as “surface 20s of the growth substrate”) serving as a support for the growth of the 2D material 10. In an embodiment, the free surface 20s of the growth substrate 20 corresponds to one of its main faces.

The growth substrate 20 can be formed of a single material, as represented in FIG. 1A. The growth substrate 20 can thus be formed of a material selected from the following materials: silicon (Si), silicon dioxide (SiO₂), sapphire (Al₂O₃), silicon carbide (SiC), germanium (Ge), gallium arsenide (AsGa), indium phosphide (InP). Alternatively, it can comprise a support layer made of a first material, for example silicon, and a surface layer made of a second material distinct from the first material. The surface layer is disposed on the support layer 11 and forms the surface 20s of the growth substrate. The second material can be selected from the following materials: aluminium (Al), copper (Cu), titanium (Ti), silicon dioxide (SiO₂), silicon nitride (Si₃N₄), alumina (Al₂O₃), nickel (Ni), graphene.

The diameter of the growth substrate 20 can be greater than 200 mm, for example 300 mm.

By way of example, the growth substrate 20 can be a silicon wafer 300 mm in diameter, with a thickness generally between 300 μm and 1000 μm, for example 775 μm, and a mechanical rigidity characterised by a Young's modulus in the order of 129 GPa.

The surface 20s of the growth substrate 20 has a sufficient wettability with respect to a liquid 50 for the liquid 50 to spread over this surface 20s.

In the following description, the term “wetting” generally covers all the phenomena (surface diffusion, mass transfer at the interface, etc.) which occur when a liquid is brought into contact with a solid surface. These phenomena depend on the combination of the nature of the liquid and the material of the solid surface.

In practice, the wettable nature of a solid surface is measured by the wetting angle, also referred to as the drop contact angle, or more simply the contact angle, that a drop of liquid makes on the solid surface.

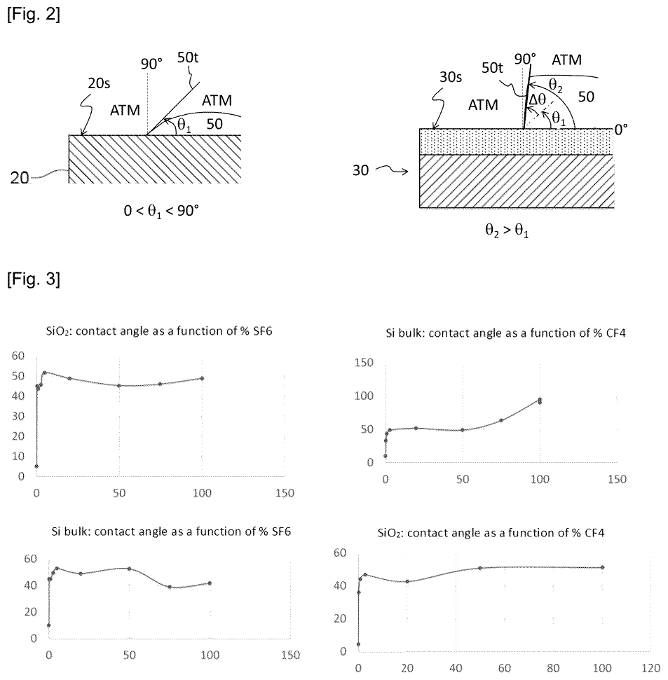

This contact angle is represented in FIG. 2 for the pair {surface 20s of the growth substrate 20; liquid 50}, where it is noted as “first contact angle θ₁”.

As shown in FIG. 2, the first contact angle θ₁ is defined between the solid surface 20s and the triple line 50t (triple interface between the external gaseous medium or atmosphere ATM, the liquid 50 and the solid surface 20s) and is strictly less than 90°. Thus, the liquid 50 spreads over the surface 20s of the substrate. It is noted that, in the remainder of the description, the external gaseous medium ATM is considered to be air.

In an embodiment, the first contact angle θ₁ is less than 30°. This allows better wetting (better spreading) of the liquid 50 on the surface 20s of the growth substrate 20.

The first contact angle θ₁ can also be zero. In this configuration, wetting is said to be “total”, i.e. a drop of liquid 50 spreads out completely to form a film having constant thickness on the surface 20s of the growth substrate. In practice, total wetting is considered to occur when a contact angle of less than 5° is measured.

The liquid is beneficially pure and non-volatile, with a low surface tension, for example less than 80 mN/m. The liquid is in an embodiment selected from the following liquids: water or an ionic solution.

For example, the liquid may be deionised water. It is noted that when the liquid is water-based, the terms “hydrophobic” and “hydrophilic” are generally used to designate, respectively, a rather non-wettable surface and a rather wettable surface.

In another example, the liquid may be a potassium hydroxide (or KOH) based solution. In yet another example, the liquid may be based on sodium hydroxide (or NaOH) in solution in water.

In an embodiment, the liquid 50 is deionised and filtered water to avoid particulate contamination.

The growth technique used to grow the 2D material 10 on the surface 20s of the growth substrate 20 may be Atomic Layer Deposition (ALD), Vapour Phase Epitaxy (VPE), Chemical Vapour Deposition (CVD) from solid or gaseous precursors, Metal Organic Chemical Vapour Deposition (MOCVD), Plasma Enhanced Chemical Vapour Deposition (PECVD), or Molecular Beam Epitaxy (MBE). It depends on the 2D material to be grown. The technique employed generates van der Waals forces between the 2D material 10 and the surface 20s of the growth substrate 20.

The target substrate 30 is also in the form of a wafer.

The diameter of the target substrate 30 can be greater than 200 mm, for example 300 mm.

The target substrate 30 may comprise a support layer 31, for example of silicon or germanium, and a surface layer 32 disposed on the support layer 31, as represented by FIG. 1A.

The surface layer 31 is formed of a material selected from (but not limited to) the following materials: silicon (Si), germanium (Ge), silicon dioxide (SiO₂), silicon nitride (Si₃N₄) or sapphire (Al₂O₃).

The target substrate 30 may be intended for the manufacture of integrated circuits and include electronic components or parts of electronic components, typically in the support layer 31.

Alternatively, the target substrate 30 is formed of a single material, this being selected from the following materials: silicon (Si), germanium (Ge), silicon carbide (SiC), gallium arsenide (AsGa) or sapphire (Al₂O₃).

Providing the target substrate 30 can thus comprise a sub-step of depositing the surface layer 32 onto the support layer 31.

The surface layer 32 of the target substrate 30 has a free surface forming the surface 30s of the target substrate 30.

In an embodiment, the surface 30s of the target substrate corresponds to one of its main faces.

The surface 30s of the target substrate 30 has a contact angle θ₂ between a drop of liquid 50 and the surface 30s (hereinafter noted as the “second contact angle θ₂ “hereafter) strictly greater than the first contact angle θ₁ (of the surface 20s of the growth substrate 20). This second contact angle θ₂ and thus the difference Δθ between the first and second contact angles θ₁, θ₂ are represented in FIG. 2.

Thus, the liquid 50 spreads and flows less well on the surface 30s of the target substrate than on that of the growth substrate 20. The second contact angle θ₂ approaches, reaches or exceeds the value of 90° which corresponds to the non-wetting threshold.

Stated differently, by thus providing a second contact angle θ₂ greater than the first contact angle θ₁, the liquid 50 is rather wetting on the surface 20s of the growth substrate 20, while it is rather non-wetting on the surface 30s of the target substrate 30.

The greater the difference 40 between the first and second contact angles θ₁, θ₂ the more different the wetting regime between the two surfaces 20s and 30s. Herein, the greater the difference 40, the more wetting the liquid 50 will be on the surface 20s of the growth substrate and the less wetting (until it is non-wetting) it will be on the surface 30s of the target substrate 30.

In an embodiment, the difference 40 between the first and second contact angles is greater than 10°, for example greater than 30°.

Even more beneficially, the second contact angle is more than 50° greater relative to the first contact angle. This makes it possible to obtain a surface 30s of the target substrate which has a completely non-wettable nature. In other words, this ensures that the liquid does not spread over the surface 30s of the target substrate 30.

The growth substrate 20 and/or the target substrate 30 can be surface treated to achieve the specified (desired) difference 40 between the first and second contact angles.

This type of surface treatment modifies the physico-chemical wetting properties and therefore the contact angle of substrates (precisely of their surfaces). For example, a silicon or germanium substrate that is naturally wettable by most liquids (it has a high-energy surface) can be made hardly wettable (or hydrophobic, when the liquid is water or deionised water) by these treatments. The growth substrate can also be treated to make it even more wettable: a naturally hydrophilic silicon growth substrate can, indeed, be made even more hydrophilic (or super hydrophilic).

This makes it possible to use growth and target substrates 20, 30 of the same nature. By way of example, the growth substrate 20 and the target substrate 30 can both be silicon or germanium wafers. They may even come from a same silicon or germanium source substrate split in two (each part providing a substrate).

This has the further benefit of increasing the choice of possible materials for each substrate (growth, target), since their wettability (or contact angle) can be acquired a posteriori, and does not constitute an intrinsic property of the substrate(s). The method according to an embodiment of the invention is thus versatile, in that it is capable of adapting to different substrates.

Providing the target substrate 30 may thus comprise surface treating the target substrate for the purpose of increasing value of the second contact angle, i.e. reducing wettable nature of its surface 30s.

Thus, before implementing this surface treatment, the second contact angle θ₂ of the surface 30s of the target substrate 30 has an initial value, and it has a final value after completion of this surface treatment. The final (post-treatment) value of the second contact angle θ₂ is greater than the initial value of the second contact angle θ₂ and is strictly greater than the first contact angle θ₁.

This surface treatment (also referred to as surface functionalisation) is useful, for example, when the target substrate is of silicon, germanium or silicon dioxide. Indeed, as detailed previously, the target substrate 30 then has, in its natural state, a low initial value of the second contact angle, which makes it wettable with respect to most aqueous liquids.

Several methods can then be implemented. Each method is adapted to one or more pairs of material of the surface 30s of the target substrate and liquid.

When the target substrate 30 is formed of silicon or germanium and the liquid is water or deionised water, a first category of methods consists in covering the surface 30s of the target substrate with a hydrophobic, hydrogenated mat. This makes it possible to obtain a surface 30s of the target substrate having a second contact angle of between 70° and 80°.

According to one of the methods in this first category, the surface treatment comprises a deoxidation operation consisting in removing the thin oxide layer naturally present (in the open air) on the surface of the target substrate 30 (also referred to as native oxide), followed by an operation of passivating the surface 30s of the target substrate with hydrogen atoms.

This operation of passivating the surface 30s can be carried out by quenching the target substrate 30 in a hydrogen fluoride (HF) based solution. The HF concentration of this solution is, in mass concentration, greater than 0.01%, for example greater than 1%, such as greater than 48%.

Of the concentrations specified, the highest (1%, 48%) are particularly beneficial. Indeed, they modify roughness of the material less, which thus remains very low, in the order of 2 angstroms (squared residual size of asperities). This preservation of the very low roughness of the surface 30s of the target substrate 30 makes it possible to improve bonding quality achieved during step S2.

Alternatively, the passivation operation can be carried out using hydrogen fluoride in vapour form.

Alternatively, the passivation operation can consist of vacuum treatment at high temperature, above 700° C. or, for example, above 800° C. The treatment is then carried out in a reducing atmosphere containing hydrogen. These high-temperature treatments have the effect of reducing roughness of the surface 30s of the target substrate obtained after the treatment, which is favourable to good bonding quality during step S2.

According to another method belonging to the first category of treatment methods, the surface treatment comprises an operation of epitaxially growing silicon or germanium on the surface 30s of the target substrate, so as to obtain a silicon or germanium surface layer with a thickness greater than 10 nm and even greater than 50 nm. Furthermore, before completion of this epitaxy operation, the target substrate 30 is placed in a reducing atmosphere containing hydrogen.

A second category of methods consists in covering the surface 30s of the target substrate with a fluorinated mat, which is also hydrophobic. This makes it possible to obtain a surface 30s of the target substrate with a second contact angle greater than 40°. This second category of methods offers the beenfit of being compatible with silicon dioxide target substrates (in addition to those of silicon or germanium). The methods in this second category use a fluorinated plasma, for example a nitrogen plasma comprising carbon tetrafluoride (CF₄) or sulphur hexafluoride (SF₆).

FIG. 3 represents contact angles measured on silicon target substrates (noted “Si bulk” in the figure) and silicon dioxide target substrates (noted “SiO₂” in the figure) as a function of the percentage of SF₆ or CF₄ mixed with nitrogen. As shown in FIG. 3, when the target substrate 30 is formed of SiO₂, the second

contact angle θ₂ varies little as a function of the concentration of SF₆ or the concentration of CF₄, since it is between 45° and 50°. The second contact angle θ₂ varies to a greater extent according to the concentration of SF₆ or CF₄ when the target substrate is of silicon, but second contact angles greater than 40° can be achieved. Thus, for a concentration of SF₆ of between 10% and 50%, the second contact angle is greater than 50°. Furthermore, for a CF₄ concentration greater than 70%, the second contact angle is greater than or equal to 60°.

A third category of methods consists in depositing a surface layer having high contact angles onto the surface 30s of the target substrate 30. The target substrate 30 thus treated (therefore comprising this surface layer produced by the surface treatment) constitutes the target substrate 30 used in the following step S2.

Document “Silane Modification of Glass and Silica Surfaces to Obtain Equally Oil-Wet Surfaces in Glass-Covered Silicon Micromode Applications” by Grate et al, Water Resources Research, 2013, 49 (8), 4724 describes an example of a method belonging to this third category.

In this example, the surface treatment comprises forming, on a target substrate 30 of silicon or silicon dioxide, a superhydrophobic layer based on hexamethyldisilazane (or HDMS). The term “superhydrophobic” is employed because of the very high contact angle, typically equal to or close to 100°, which is achieved on the surface once the treatment has been completed. Document “Preparation and Characterization of Superhydrophobic Surfaces Based on Hexamethyldisilazane-Modified Nanoporous Alumina.” by Tasaltin et al, Nanoscale Res Lett 2011, 6 (1), 487 describes that such an HDMS layer can also be formed of an alumina substrate.

Document “Delivering Octadecylphosphonic Acid Self-Assembled Monolayers on a Si Wafer and Other Oxide Surfaces” by Nie et al, J. Phys. Chem. B 2006, 110 (42), 21101-21108, describes another example of a method belonging to the third category. According to this method, the surface treatment can include an operation of forming Self-Assembled Monolayers (also referred to as SAMs) of octadecylphosphonic acid (or OPA) on the surface 30s of the target substrate 30, using a non-polar medium with a dielectric constant of about 4 (for example, trichloroethylene). This method has the benefit of being compatible with many oxide surfaces. It also makes it possible to obtain a lower final residual roughness than that obtained when a layer of HDMS is formed.

As previously mentioned, the growth substrate 20 may also undergo a surface treatment aiming at lowering the first contact angle θ₁. In other words, the surface 20s of the growth substrate 20 then has an initial value before the implementation of this surface treatment, and a final value after the completion of this surface treatment. The final (post-treatment) value of the first contact angle is less than the initial value of the first contact angle and strictly less than the second contact angle.

In step S2 of FIG. 1B, the growth substrate 20 (covered with the 2D material 10) and the target substrate 30 are assembled by direct bonding (in other words, without supply of adhesive or metallic material) between the 2D material 10 and the surface 30s of the target substrate 30. The free surface of the 2D material 10 is thus brought into (direct) contact with the surface 30s of the target substrate 30.

Bonding S2 is generally implemented at ambient temperature and ambient pressure. However, it can also be implemented under vacuum and at ambient temperature. Alternatively, bonding S2 can be implemented at a temperature of between 25° C. and 400° C., for example 100° C.

The 2D material 10 is then linked by van der Waals forces to the surface 30s of the target substrate 30, herein constituted by the material of the surface layer 32 (see FIG. 1B). The interface between the 2D material and the target substrate 30 is noted “I2” in FIG. 1B.

The bonding surfaces, namely the free surface of the 2D material 10 and the surface 30s of the target substrate 30, beneficially have a surface roughness of less than 0.5 nm and even less than 0.2 nm. This roughness value, as well as all those given hereafter, are expressed as a root mean square value. The root mean square roughness (noted as Rq) is determined by statistical analysis of an atomic force microscope image, taking a 1×1 μm² surface area as the sample.

2D material growth techniques make it possible to obtain a surface roughness of less than 0.5 nm and even less than 0.2 nm. On the other hand, the target substrate 30 may have undergone, between the step S1 of providing the target substrate 30 and the bonding assembly step S2, a step of polishing (for example by chemical mechanical planarisation or CMP) its bonding surface 30s so as to achieve a surface roughness value of less than 0.5 nm and even less than 0.2 nm.

At the end of step S2, the assembly 40 represented in FIG. 1B is obtained. As shown in FIG. 1B, this assembly 40 is a multi-material monoblock since it successively comprises, from bottom to top in the figure, the target substrate 30, the interface I2, the 2D material 10, the interface I1 and the growth substrate 20.

The bi-material interfaces I1, I2 have a thickness (measured perpendicular to the plane of the assembly 40) of less than or equal to 1 nm on average.

Finally, step S3 of FIG. 1C (in particular the figure on the right of FIG. 1C) consists in separating the growth substrate 20 and the target substrate 30 so that at least part of the 2D material 10 is detached from the growth substrate 20 and remains bonded to the target substrate 30.

As shown in FIG. 1C (in particular the figure on the left), separating the growth substrate 20 and the target substrate 30 is achieved by breaking the interface I1 between the growth substrate 20 and the 2D material 10 by propagating, in this interface I1, an interfacial crack F wetted up to its front Fa with the liquid 50.

One way of wetting the crack front Fa throughout the advance of the crack F is to move the crack front Fa at a sufficiently slow speed for the liquid 50 to spread up to this front Fa.

Keeping the crack front Fa wetted with the liquid 50 makes it possible, especially, to ensure that the crack F is restricted in the interface I1. In other words, this allows breaking to be an adhesive-type rupture, i.e. breaking occurs at the interface I1, the 2D material being retained on the surface 30s of the target substrate 30 and the growth substrate being separated from the assembly 40. This allows the 2D material to be successfully transferred.

Moreover, this enables the liquid 50 (which forms a film) to be driven over the entire surface 20s of the growth substrate 20, even when the latter has a large surface area (diameter of 200 mm or even 300 mm). It is remembered that, unlike the solutions of prior art, the liquid 50 cannot here infiltrate naturally over the surface 20s of the growth substrate, due to the rigidity of the target substrate and its surface area.

Herein, by virtue of the liquid 50 which wets the crack F up to its front Fa, the growth substrate and the 2D material are interposed by this film of liquid 50 and are therefore separated.

Wetting the crack front Fa by the liquid 50 helps to reduce interface energy between the 2D material 10 and the growth substrate 20, thus facilitating propagation of the crack F, which can then develop more easily into an interfacial crack extending over virtually the entire interface I1.

Separating S3 the growth substrate 20 and the 2D material can especially be achieved in the manner described hereinafter.

The assembly 40 is placed in an external environment such that a front of the liquid 50 forms in contact with the assembly 40 (and therefore at the crack front Fa of the interface I1).

This external environment may be a liquid medium consisting of the liquid 50 itself. In this case, the assembly is immersed in the liquid 50.

Alternatively, the external environment may be a gaseous atmosphere comprising excess liquid in vapour form. Thus, the liquid in vapour form condenses in contact with the assembly 40. For example, the environment may be air with 80% or more humidity (water vapour).

In order to initiate and propagate the interfacial crack, a mechanical load is applied to the assembly 40, from priming sites provided by the assembly 40.

In an embodiment, these priming sites are located on the external (peripheral) surface of the 2D material 10 of the assembly 40.

In practice, a blade L, wedge (or tip) or wire may be inserted between the growth substrate 20 and the target substrate 30, either manually or by means of a machine. Alternatively, a force can be exerted on at least one of the substrates (or wafers). It will be appreciated that other mechanical stress means can be used. For example, it is possible to apply traction by means of jaws bonded to the rear faces of the growth and target substrates 20, 30, in the place of the first mechanical load. It is possible to have only one jaw by clamping (pinching) the growth substrate or the target substrate to a support, for example with vacuum. It is possible to replace the jaw(s) with rings which use chamfers of the growth and target substrates 20,30 to exert traction in the manner described in document U.S. Pat. No. 9,583,374B2.

In the following description, it is considered that the stress means used to implement the first mechanical load is a blade L such as that represented in FIG. 1C. However, its teachings are also valid for other mechanical stress means, especially the wedge and the wire.

The mechanical load can be decomposed into two successive mechanical loads.

In a first time, a first mechanical load causes an initial detachment of the 2D material relative to the growth substrate 20.

This first mechanical load is quite delicate because, when the wedge or blade is inserted, the speed of cracking can quickly exceed 100 μm/s. Indeed, the wedge or blade is very close to the crack front Fa. It is thus desirable, to make the first mechanical load, to use means that enable traction to be applied to either or both of the substrates (growth, target). The use of a ring in the chamfer is well adapted, for example.

The first mechanical load may nevertheless produce, in an undesired manner, a crack in the interface I2 between the target substrate 30 and the 2D material 10. This possible presence of a crack in the interface I2 is not problematic, however, for the reasons hereinafter given.

Because of the difference between the first and second contact angles, the liquid 50 is wetting for the surface 20s of the growth substrate at the interface I1 of the assembly, but hardly or not wetting for the surface 30s of the target substrate at the interface I2. As a result, the liquid 50 from the environment external to the assembly 40 infiltrates at the edges of this crack or through some structural defects in the 2D material to return and in an embodiment wet the interface I1 between the 2D material 10 and the growth substrate 20. This then allows the crack to bifurcate at the correct interface (interface I1) when the opening speed drops back below 100 μm/s.

On the other hand, this liquid 50 does not infiltrate to the side or through any of the defects in the 2D material 10 towards the interface I2 between the 2D material 10 and the target substrate 30 by virtue of the absence of wetting on the surface 30s of the target substrate 30. No process that could cause bifurcation of the crack is therefore activated at this interface I2. Consequently, this interface I2 remains intact and the 2D material remains bonded to the target substrate 30.

Thus, by virtue of the wetting properties specified for the surfaces 20s, 30s of the growth and target substrates, separating the growth substrate and the target substrate is selectively achieved (as it relates to the interface I1) and in a simple manner: immersing the assembly 40 into the liquid 50 is simple to implement and the mechanical load does not require nanometrically precise equipment (on the scale of the thickness of the interface I1).

The thickness el of the blade L is selected so that the initial detachment is sufficiently slow (soft) for the front of this detachment to advance at the wetting speed of the liquid 50 on the surface 20s of the growth substrate 20.

In an embodiment, a blade with a thickness of less than 500 μm, for example less than 300 μm, and for example with a thickness of 100 μm, can be used to exert the first mechanical load.

When the thickness of the blade is between 500 μm and 100 μm, the propagation speed of the initial detachment is generally much higher than the wetting speed of the liquid 50 on the surface 20s of the growth substrate forming the interface I1. Detachment can then sometimes take place at the interface I2 as previously explained.

To reduce extent of this initial detachment, and thus transfer the 2D material as much as possible, thickness of the blade can beneficially be reduced to 100 μm or less. This makes it possible to control the propagation speed of the front Fa of the initial detachment so that it is low enough to avoid or minimise a poor initial detachment. In practice, the blade L is connected to a linear motor driving means configured to move the blade L at a speed which is for example less than or equal to 100 μm/s.

The insertion speed of the blade L can then be selected to be less than or equal to 100 μm/s, for example less than or equal to 10 μm/s, such as less than or equal to 1 μm/s, which corresponds, respectively, to a propagation speed of the detachment front of less than or equal to 100 μm/s, for example less than or equal to 10 μm/s, such as less than or equal to 1 μm/s.

Such ranges of insertion (and crack propagation) speeds allow the area of 2D material transferred to be increased, since the zone corresponding to the initial detachment, where the 2D material is not transferred, is reduced. For example, this zone may represent less than 10% of the surface area of the 2D material.

Mechanical stress then continues to propagate the initial detachment and thus develop it into the interfacial crack F. This second phase of mechanical load is referred to as the “second mechanical load”. In other words, the second mechanical load “takes over” from the first mechanical load.

The second mechanical load can be identical to the first mechanical load in that it can be carried out with the same stress means (e.g. blade, wedge, wire, rings, jaws). For example, the same blade L as previously described can be used, and inserted with the same insertion speed as that configured for the first mechanical load, i.e. a speed of less than or equal to 100 μm/s, for example less than or equal to 10 μm/s, even more such as less than or equal to 1 μm/s.

Alternatively, the insertion speed may be lower during the first mechanical load than during the second mechanical load. This makes it possible to compensate for the speed of progression of the initial detachment, which is fast compared with that of the progression of the crack F. For example, the insertion speed of the blade during the first mechanical load is less than or equal to 1 μm/s, and the insertion speed of the blade during the second mechanical load is less than or equal to 100 μm/s and greater than 1 μm/s. A blade of variable thickness (thinner to prime the crack than to propagate it) can also be contemplated.

This second mechanical load is exerted on the assembly 40 until interfacial breaking I1 is completed.

The temperature of the liquid 50 can be regulated between 15° C. and 25° C., for example 20° C.

Beneficially, the temperature of the liquid 50 can be lowered so as to increase the contact angle of the surface 30s of the target substrate 30 in situ. This makes it possible to increase the non-wetting nature of this surface 30s. Interfacial breaking is then more effective. The temperature of the liquid 50 is in an embodiment greater than or equal to 5° C. and less than or equal to 10° C.

Thus, by virtue of the wettable nature of the surface 20s of the growth substrate 20 and the non-wettable nature of the surface 30s of the target substrate 30, as well as the configuration of the mechanical load and the external environment of the assembly 40, a majority, typically up to about 90% of the surface area of the growth substrate, of adhesive-type interface rupture is produced at the interface I1 between the 2D material 10 and the growth substrate 20. This enables the 2D material 10 to be successfully transferred over a large surface area (typically more than 90% of the surface area of the growth substrate).

In other words, by virtue of the wettable nature of the surface 20s of the growth substrate 20 and the non-wettable nature of the surface 30s of the target substrate 30, the configuration of the mechanical load and the external environment of the assembly 40, adhesive rupture at the interface I2 between the 2D material 10 and the target substrate 30 is avoided, which would result in a lack of transfer of the 2D material.

The 2D material 10 is thus transferred from the growth substrate 20 to the target substrate 30, avoiding the 2D material being left without a support. Furthermore, unlike transfer methods of prior art, the method avoids the use of a support layer dedicated to holding the 2D material (which has to be formed and then removed). The target substrate, which is rigid (given thicknesses of the wafers and their Young's modulus), replaces this support layer.

This avoids bringing about deformations such as wrinkles or holes in the 2D material, since the 2D material is never left without sufficient mechanical support.

The method also dispenses with the steps of forming and removing the sacrificial support layer. It does not generate any polymer or metal residue, or cause any deterioration, as no material is deposited onto the 2D material, unlike the transfer methods of prior art.

As a result, the method of FIGS. 1A-1C is particularly easy to implement, compatible with clean-room environments of the microelectronics industry and enables large-area 2D material to be transferred. In particular, it can be implemented with wafers 200 mm or 300 mm in diameter.

The method of FIGS. 1A-1C is applicable to both a single-layer 2D material and a multi-layer 2D material.

When the 2D material 10 is comprised of a single mono-atomic or mono-molecular sheet, this sheet is detached from the growth substrate 30 during the separation step.

When the 2D material 10 is comprised of a stack of several (typically three) mono-atomic or mono-molecular sheets, this stack is detached as a block from the growth substrate 30 during the separation step.

A first exemplary embodiment of the production method will now be described.

### Step S1

A stack of three MoS₂ monolayers has been obtained on a growth substrate 20 with a diameter of 200 mm, according to the method described in document [«Élaboration de monocouches de dichalcogénures de métaux de transition du groupe (VI) par chimie organométallique de surface», S. Cadot, Matériaux. Université de Lyon, 2016. Français. NNT: 2016LYSE1075. tel-01530918]. This method comprises an ALD deposition step at low temperature (about 100° C.) and a material crystallisation step at high temperature (900° C.) to obtain the lamellar structure typical of 2D materials.

The growth substrate 20 is a 200 mm diameter wafer which comprises a support layer (or base layer) of silicon and a surface layer of SiO₂, obtained for example by thermal oxidation of the support layer of silicon.

According to a first alternative implementation, the surface of the SiO2 surface layer is cleaned and has a wetting contact angle of at least 10° before growing the 2D material.

According to a second alternative implementation, the surface of the surface layer is not cleaned and has (in its natural state) a wetting contact angle of between 20° and 30° before growing the 2D material.

The target substrate 30 provided is entirely of silicon.

In order to increase the droplet contact angle of the surface 30s of the target substrate 30, the target substrate is surface treated.

The surface treatment comprises epitaxially growing silicon on the surface 30s of the target substrate. The epitaxy is carried out using dichlorosilane (SiH₂Cl₂) at 950° C.

Epitaxy is described in more detail hereinafter.

The surface 30s of the target substrate 30 is first prepared according to a so-called “HF last” method. The preparation comprises chemical cleaning with Caro's acid (obtained by mixing phosphoric acid H₂SO₄ and hydrogen peroxide H₂O₂ at 120° C.).

Cleaning is followed by rinsing with deionised water and treating with a mixture of ammonia, hydrogen peroxide and water in a 1/1/5 proportion at 70° C.

Rinsing is followed by deoxidation in a 0.1% mass concentration HF bath, followed by rinsing with deionised water.

Each operation (cleaning, rinsing, deoxidation) takes about 10 minutes.

After this cleaning and chemical preparation, the target substrate 30 is brought to 950° C. under 20 mbar of hydrogen for 2 minutes. Silicon epitaxial growth is then performed on the prepared surface of target substrate 30 for about 10 min at 950° C. under 20 mbar of SiH₂Cl₂.

Finally, the epitaxy is completed by smoothing annealing at 950° C. under 20 mbar of dihydrogen H₂ for 5 min.

Atomic force microscopy images of the epitaxially grown surface of the target substrate 30 have been acquired. These images show very low surface roughness, typically less than 0.5 nm. This low roughness is perfectly compatible with direct bonding.

After epitaxy, the surface of the target substrate is passivated with hydrogen by virtue of annealing in a hydrogen-based atmosphere. This target substrate surface has a drop contact angle between 70° and 90°.

### Step S2

The growth substrate 20 and the target substrate 30 are then assembled by direct bonding between the 2D material 10 and silicon of the target substrate 30, for example at ambient temperature and in ambient air. Bonding is spontaneous, with the propagation of a fairly fast bonding wave (about 20 s to travel the 200 mm diameter).

In an embodiment, direct bonding is carried out just after the 2D material has grown to avoid any particulate contamination.

Alternatively, the growth substrate and 2D material are stored in a specific environment free of dust and hydrocarbon contaminants. For example, they are stored in a specific box like the one supplied by the company Entegris (DMS Wafer Carrier 8″ black antistatic TYP A5 no 780-550000005). Bonding remains the same even after 1 month.

### Step S3

Separating the growth substrate 20 and the target substrate 30 is achieved by immersion in deionised water (DIW) regulated at 21° C.

The assembly of the growth substrate and the target substrate can remain immersed prior to separation for one day. It can remain immersed for longer, for example more than 10 days, without degradation of bonding being observed.

Breaking the interface between the growth substrate and the 2D MoS₂ material (and therefore separation of the growth substrate) is initiated by introducing a blade at a speed of 1 μm/s and an acceleration of 10 μm²/s. This speed is regulated using a linear motor. Hydrophilicity of SiO₂ (from the surface 20s of the growth substrate 20) allows deionised water to advance to the SiO₂/MoS₂ interface and the substrates to be separated at this interface.

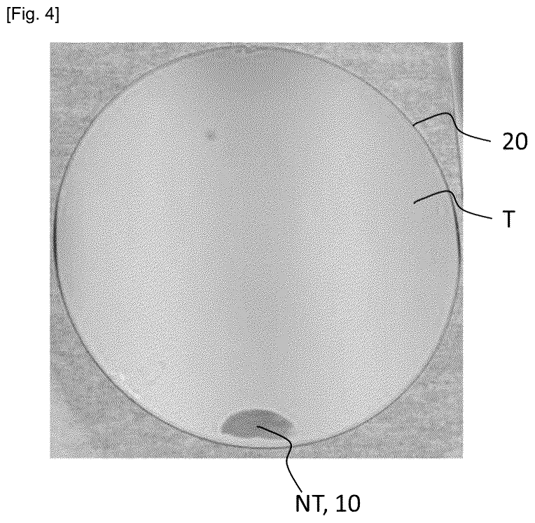

The 2D material 10 is thus transferred onto the silicon target substrate 30 because the interface between the target substrate and the 2D material, which is hydrophobic, does not undergo any interfacial fracture. As shown in FIG. 4, all the MoS2 monolayers are herein transferred, over 90% of the surface area of the target substrate (the light grey zone noted T corresponds, in this photograph of the growth substrate, to the zones where the 2D material 10 has been transferred. The zones noted NT correspond, for their part, to the zones where the 2D material 10 appears because it has not been transferred).

A second exemplary embodiment of the production method will now be described.

### Step S1

In this second example, the same growth substrate 20 with the same MOS2 2D material is used as in the first exemplary embodiment. The operations of preparing the growth substrate and growing the 2D material are identical too.

The target substrate 30 provided is another silicon wafer with a diameter of 200 mm.

This substrate undergoes a different surface treatment to that implemented in the first example.

The surface treatment herein comprises cleaning the target substrate 30

with Caro's acid (obtained by mixing phosphoric acid H₂SO₄ and hydrogen peroxide H₂O₂ at 120° C.).

The target substrate 30 is then rinsed with deionised water.

Cleaning based on SC1 comprised of a mixture of water, ammonia and oxygenated water in 5:1:1 proportions at 70° C. is then implemented on the target substrate rinsed.

The target substrate is then soaked in a 10% mass HF solution for 20s. This operation removes the native oxide and passivates the hydrogen surface.

It is possible to rinse with deionised water for 10 s without disturbing the hydrogen passivation.

### Steps S2 and S3

Bonding S2 the target substrate to the 2D material and separating S3 the growth substrate are identical to the first example.

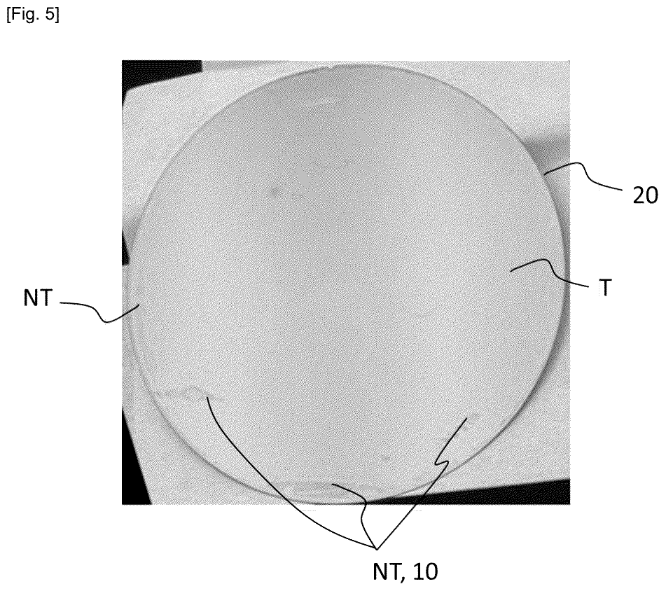

As shown in FIG. 5, a slightly less good transfer of 2D material, i.e. less homogeneous and over a smaller area, than in the first example (see FIG. 4) is achieved. However, more than 80% of the 2D material is transferred, which is satisfactory for many applications.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A method for producing and transferring a two-dimensional material, comprising:
growing the two-dimensional material on a surface of a growth substrate such that the two-dimensional material is linked to the surface of the growth substrate by van der Waals forces, the surface of the growth substrate having a first contact angle with a drop of a liquid;
providing a target substrate having a surface with a second contact angle with a drop of the liquid, the second contact angle being strictly greater than the first contact angle;
assembling the growth substrate and the target substrate by direct bonding between the two-dimensional material and the surface of the target substrate; and
breaking the interface between the growth substrate and the two-dimensional material, by applying a mechanical load to the assembly of the growth substrate and the target substrate to generate and propagate a crack front at the interface between the growth substrate and the two-dimensional material, and by placing the assembly of the growth substrate and the target substrate in an environment such that a liquid front forms at the interface between the growth substrate and the two-dimensional material, the mechanical load being configured such that the crack front is wetted with the liquid.

2. The method according to claim 1, wherein the difference between the first and second contact angles is strictly greater than 10°.

3. The method according to claim 2, wherein the difference between the first and second contact angles is strictly greater than 30°.

4. The method according to claim 3, wherein the difference between the first and second contact angles is strictly greater than 50°.

5. The method according to claim 1, wherein providing the target substrate comprises treating the surface of the target substrate so as to increase the second contact angle.

6. The method according to claim 1, comprising, prior to growing the two-dimensional material, treating the surface of the growth substrate so as to reduce the first contact angle.

7. The method according to claim 1, wherein the mechanical load is configured to allow the crack front to advance at a speed of less than or equal to 100 μm/s.

8. The method according to claim 7, wherein the speed is less than or equal to 10 μm/s.

9. The method according to claim 8, wherein the speed is less than or equal to 1 μm/s.

10. The method according to claim 1, wherein the mechanical load is exerted by a blade with a thickness less than or equal to 500 μm.

11. The method according to claim 10, wherein the mechanical load is exerted by a blade with a thickness less than or equal to 300 μm.

12. The method according to claim 11, wherein the mechanical load is exerted by a blade with a thickness less than or equal to 100 μm.

13. The method according to claim 12, wherein the thickness of the blade is less than or equal to 100 μm, and the blade is inserted at a first speed to initiate the crack and at a second speed to propagate the crack in the interface between the growth substrate and the two-dimensional material, the first speed being less than or equal to 1 μm/s, and the second speed being greater than the first speed and less than or equal to 100 μm/s.

14. The method according to claim 1, wherein, during the breaking of the interface between the growth substrate and the two-dimensional material, the assembly of the growth substrate and the target substrate is placed in the liquid.

15. The method according to claim 1, wherein the liquid is deionised water or an ionic solution.

16. The method according to claim 1, wherein, during the breaking of the interface between the growth substrate and the two-dimensional material, the assembly of the growth substrate and the target substrate is placed in a gaseous medium comprising deionised water vapour or an ionic solution vapour.

17. The method according to claim 1, wherein the two-dimensional material is graphene, hexagonal crystal structure boron nitride or a transition metal dichalcogenide.

18. The method according to claim 1, wherein the surface of the growth substrate and the surface of the target substrate are each formed of a material selected from silicon (Si), germanium (Ge), silicon dioxide (SiO₂), silicon carbide (SiC), indium phosphide (InP), gallium arsenide (AsGa) and sapphire (Al₂O₃).

19. The method according to claim 1, wherein the surface of the growth substrate is formed of a silicon or germanium base layer covered with a surface layer of a material selected from the following materials: silicon dioxide (SiO₂), silicon nitride (Si₃N₄), aluminium (Al), copper (Cu), titanium (Ti), alumina (Al₂O₃), nickel (Ni), graphene.
